(19) United States
(12) Patent Application Publication
(10) Pub. No.: US 2018/0151761 A1
(43) Pub. Date: May 31, 2018

(54) DISPLAY DEVICE

(71) Applicant: Japan Display Inc., Minato-ku (JP)

(72) Inventor: Yasushi KAWATA, Tokyo (JP)

(73) Assignee: Japan Display Inc., Minato-ku (JP)

(21) Appl. No.: 15/813,304

(22) Filed: Nov. 15, 2017

(30) Foreign Application Priority Data
Nov. 30, 2016 (JP) 2016-233164

(51) Int. Cl. H01L 31/0224; G02F 1/1335; C23C 14/08

(52) U.S. Cl. CPC H01L 31/022475; C23C 14/086; G02F 1/133553; G02F 1/133536

(57) ABSTRACT

According to one embodiment, a display device includes a metal line, a first reflection suppressing layer, a second reflection suppressing layer. The first reflection suppressing layer is formed on the metal line. The second reflection suppressing layer is formed on the first reflection suppressing layer. The first reflection suppressing layer is formed of indium tin oxide or reduced indium tin oxide.

### CROSS-REFERENCE TO RELATED APPLICATIONS

This application is based upon and claims the benefit of priority from Japanese Patent Application No. 2016-233164, filed Nov. 30, 2016, the entire contents of which are incorporated herein by reference.

### FIELD

Embodiments described herein relate generally to a display device.

### BACKGROUND

A transparent conductive material formed of indium tin oxide (ITO) or the like has a large electric resistance as compared with a metallic material. To reduce the electric resistance, metallic lines formed of a metallic material such as molybdenum tungsten (MoW) or the like are often disposed in a display area of a display device.

The metallic lines have a property of reflecting light while its electric resistance is small. If external light is reflected on the metal line, the display quality of the display device is degraded. For this reason, light-shielding members of black matrix or the like are disposed on counter-substrates and array substrates.

If the black matrix becomes large, the screen becomes darker. For this reason the reflection of external light needs to be suppressed by forming a reflection suppressing layer on the metallic line. Formation of a film of reduced indium tin oxide (reduced ITO) as the reflection suppressing layer has been well known. When reduced ITO suppressing the reflection by the interference of light is used, however, if a film of silicon nitride (SiN) is further formed on the surface of the reflection suppressing layer, deviation occurs in designed light interference conditions. As a result, reduced ITO covered with SiN does not function as the reflection suppressing layer.

In addition, formation of a film of titanium nitride (TiN) as the reflection suppressing layer has been conceived. When TiN suppressing the reflection by the absorption of light is used, however, the film does not sufficiently function as the reflection suppressing layer unless its thickness is increased. Since TiN has a large residual stress, the display device may be bent if the film thickness is increased. In addition, if the film thickness is increased, TiN is peeled from the metal line and dust occurs.

Furthermore, use of a different material as the reflection suppressing layer has been conceived. If such a material is used, however, the number of steps of manufacturing the display device needs to be increased and large change of design is required.

### BRIEF DESCRIPTION OF THE DRAWINGS

FIG. 1 is a plan view schematically showing a basic configuration and an equivalent circuit, of a liquid crystal display device which is an example of the display device.

FIG. 2 is a cross-sectional view showing a configuration of a display panel on a pixel shown in FIG. 1.

FIG. 3 is an enlarged cross-sectional view showing an example of a metal line shown in FIG. 2.

FIG. 4 is a graph showing an interaction between a thickness of a first reflection suppressing layer and a thickness of a third insulating film.

FIG. 5 is a graph showing an interaction between the thickness of the first reflection suppressing layer and a thickness of a second reflection suppressing layer.

FIG. 6 is a graph showing an interaction between a thickness of a third insulating film and the thickness of the second reflection suppressing layer.

FIG. 7 is a graph showing an interaction between the thickness of the second reflection suppressing layer and the thickness of the first reflection suppressing layer.

FIG. 8 is a graph showing an interaction between the thickness of the second reflection suppressing layer and a material of the first reflection suppressing layer.

FIG. 9 is a graph showing an interaction between the material of the first reflection suppressing layer and the thickness of the first reflection suppressing layer.

FIG. 10 is a graph showing a main effect of the thickness of the first reflection suppressing layer extracted from FIG. 4 and FIG. 5.

FIG. 11 is a graph showing a main effect of the thickness of the third insulating film extracted from FIG. 4 and FIG. 6.

FIG. 12 is a graph showing a main effect of the thickness of the second reflection suppressing layer extracted from FIG. 7 and FIG. 8.

FIG. 13 is a graph showing a main effect of the thickness of the second reflection suppressing layer extracted from FIG. 5 and FIG. 6.

### DETAILED DESCRIPTION

In general, according to one embodiment, a display device includes a metal line, a first reflection suppressing layer, a second reflection suppressing layer. The first reflection suppressing layer is formed on the metal line. The second reflection suppressing layer is formed on the first reflection suppressing layer. The first reflection suppressing layer is formed of indium tin oxide or reduced indium tin oxide.

Embodiments will be described hereinafter with reference to the accompanying drawings. Incidentally, the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, and the like of the respective parts are schematically illustrated in the drawings, compared to the actual modes. However, the schematic illustration is merely an example, and adds no restrictions to the interpretation of the invention. Besides, in the specification and drawings, the structural elements having functions, which are identical or similar to the functions of the structural elements described in connection with preceding drawings, are denoted by like reference numerals, and an overlapping detailed description is omitted unless otherwise necessary.

Each of the embodiments discloses a display device DSP which is a liquid crystal display device as an example of the display device. However, various embodiments do not prevent application of technical idea disclosed in each of the embodiments to display devices of the other types. The major configuration disclosed in each of the embodiments can also be applied to a self-luminous display device comprising an organic electroluminescent display element, and the like, an electronic paper display device comprising a cataphoretic element, and the like, a display device employing micro-electromechanical systems (MEMS), or a display device employing electrochromism. The display device DSP can be used for, for example, various devices such as a smartphone, a tablet terminal, a mobile telephone terminal, a personal computer, a TV receiver, a vehicle-mounted device, a game console and a wearable terminal.

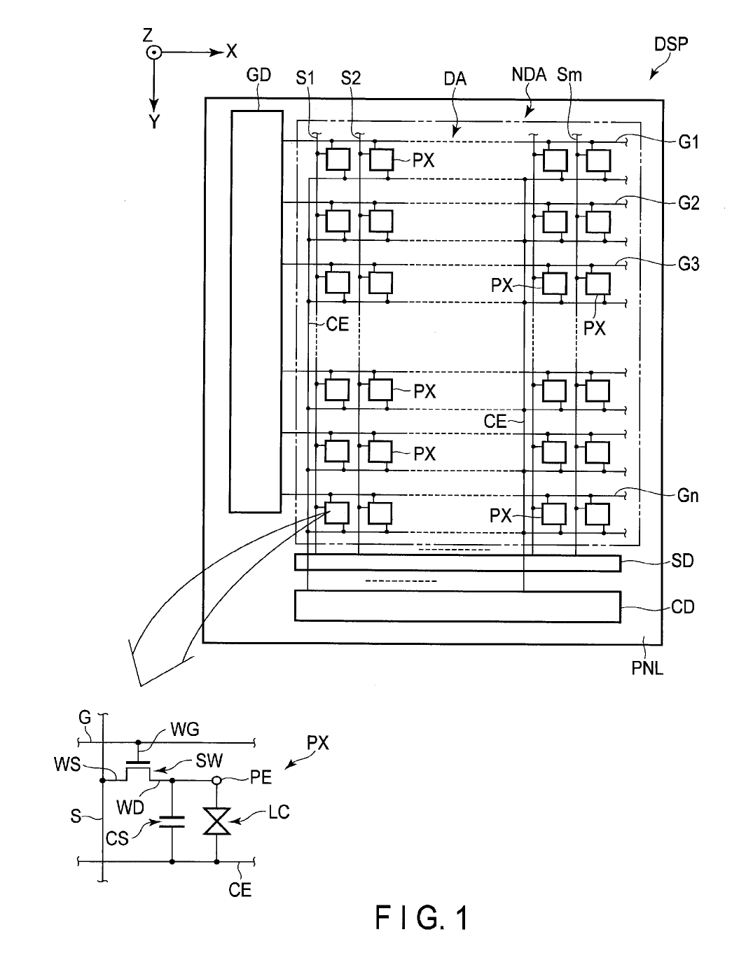

FIG. 1 is a plan view schematically showing a basic configuration and an equivalent circuit, of the display device DSP. FIG. 1 shows an X-Y plane defined by a first direction X and a second direction Y. In addition, a third direction Z is perpendicular to each of the first direction X and the second direction Y. In the example illustrated, the first direction X, the second direction Y, and the third direction Z are orthogonal to each other but may intersect at an angle other than ninety degrees.

As shown in FIG. 1, the display device DSP comprises a display panel PNL. The display device DSP may further comprise a touch panel and the like superposed on the display panel PNL, though not illustrated in the drawing. The display panel PNL includes a display area DA on which an image is displayed and a frame-shaped non-display area NDA surrounding the display area DA. In the display area DA, scanning lines G (G1 to Gn), signal lines S (S1 to Sm), a common electrode CE and the like are disposed.

The scanning lines G extend in the first direction X and are arranged in the second direction Y. The signal lines S extend in the second direction Y and are arranged in the first direction X. The scanning lines G and the signal lines S may not extend linearly, but may be partially bent.

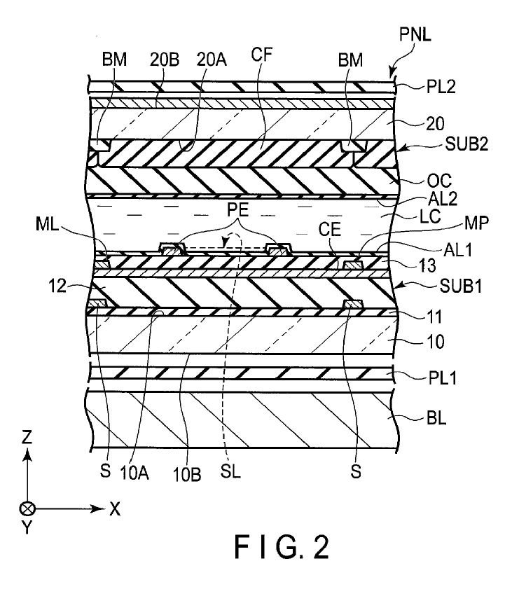

The scanning lines G, the signal lines S, and the common electrode CE are drawn to the non-display area NDA. In the non-display area NDA, the scanning lines G are connected to a scanning line drive circuit GD, the signal lines S are connected to a signal line drive circuit SD, and the common electrode CE is connected to a common electrode drive circuit CD. The signal line drive circuit SD, the scanning line drive circuit GD, and the common electrode drive circuit CD are formed on, for example, a first substrate SUB1 (shown in FIG. 2) to be explained below to output signals necessary for image display.

In addition, pixels PX are arranged in a matrix in the display area DA. The pixel PX is the minimum unit which can be controlled individually in response to the pixel signal and is an area including, for example, a switching element SW disposed at a position where the scanning line G (G1 to Gn) intersects the signal line S (S1 to Sm).

Each of the pixels PX comprises the switching element SW, a pixel electrode PE, the common electrode CE, a liquid crystal layer LC and the like. The switching element SW is composed of, for example, a thin-film transistor (TFT) and is electrically connected to the scanning line G and the signal line S. More specifically, the switching element SW comprises a gate electrode WG, a source electrode WS, and a drain electrode WD. The gate electrode WG is electrically connected to the scanning line G. In the example illustrated in FIG. 1, the electrode electrically connected to the signal line S is the source electrode WS while the electrode electrically connected to the pixel electrode PE is the drain electrode WD.

The scanning line G is connected to the switching element SW in each of the pixels PX arranged in the first direction X. The signal line S is connected to the switching element SW in each of the pixels PX arranged in the second direction Y. Each of the pixel electrodes PE is opposed to the common electrode CE and drives the liquid crystal layer LC by an electric field generated between the pixel electrode PE and the common electrode CE. A storage capacitor CS is formed, for example, between the common electrode CE and the pixel electrode PE.

FIG. 2 is a cross-sectional view showing the configuration of the display panel PNL at the pixel PX. The display panel PNL comprises a first substrate (array substrate) SUB1 and a second substrate (counter-substrate) SUB2 opposed to each other through the liquid crystal layer LC. In the third direction Z, an orientation from the first substrate SUB1 to the second substrate SUB2 is called an upward side and an orientation from the second substrate SUB2 to the first substrate SUB1 is called a downward side.

The display panel PNL may be a transmissive display panel which displays an image by causing the light from the lower side of the first substrate SUB1 to be selectively transmitted or a reflective display panel which displays an image by causing light from the upper side of the second substrate SUB2 to be selectively reflected. Alternately, the display panel PNL may be a transflective display panel comprising both of the feature of causing the light to be transmitted and the feature of causing the light to be reflected.

In addition, in the example illustrated in FIG. 2, the display panel PNL is configured to correspond to the display mode mainly using the lateral electric field approximately parallel to the X-Y plane. The display panel PNL may be configured to correspond to a display mode using a longitudinal electric field vertical to the X-Y plane, an inclined electric field inclined to the X-Y plane or these electric fields in combination.

In the display mode using the lateral electric field, for example, both of the pixel electrode PE and the common electrode CE can be disposed on either of the first substrate SUB1 and the second substrate SUB2. In the display mode using the longitudinal electric field or the inclined electric field, for example, either of the pixel electrode PE and the common electrode CE can be disposed on the first substrate SUB1 and the other of the pixel electrode PE and the common electrode CE can be disposed on the second substrate SUB2. In any one of the display modes, a metal layer ML to be explained below is electrically connected to the common electrode CE just above the signal line S or the scanning line G.

The first substrate SUB1 includes a first insulating substrate 10, the signal lines S, the common electrodes CE, metal wiring portions MP, the pixel electrodes PE, a first insulating film 11, a second insulating film 12, a third insulating film 13, a first alignment film AL1 and the like. Switching elements, scanning lines, various insulating films interposed between these elements, and the like are not shown in FIG. 2.

The first insulating substrate 10 has a main surface 10A opposed to the second substrate SUB2 and a main surface 10B opposed to the main surface 10A. The first insulating film 11 is an inorganic insulating film and is disposed on a main surface 10A. A semiconductor layer for the scanning lines and the elements (not shown) is interposed between the first insulating substrate 10 and the first insulating film 11.

The signal lines S are disposed on the first insulating film 11. The second insulating film 12 is an organic insulating film and is disposed on the signal lines S and the first insulating film 11. The common electrode CE is disposed on the second insulating film 12. The common electrode CE is a transparent electrode formed of a transparent, electrically conductive material such as indium tin oxide (ITO) or indium zinc oxide (IZO).

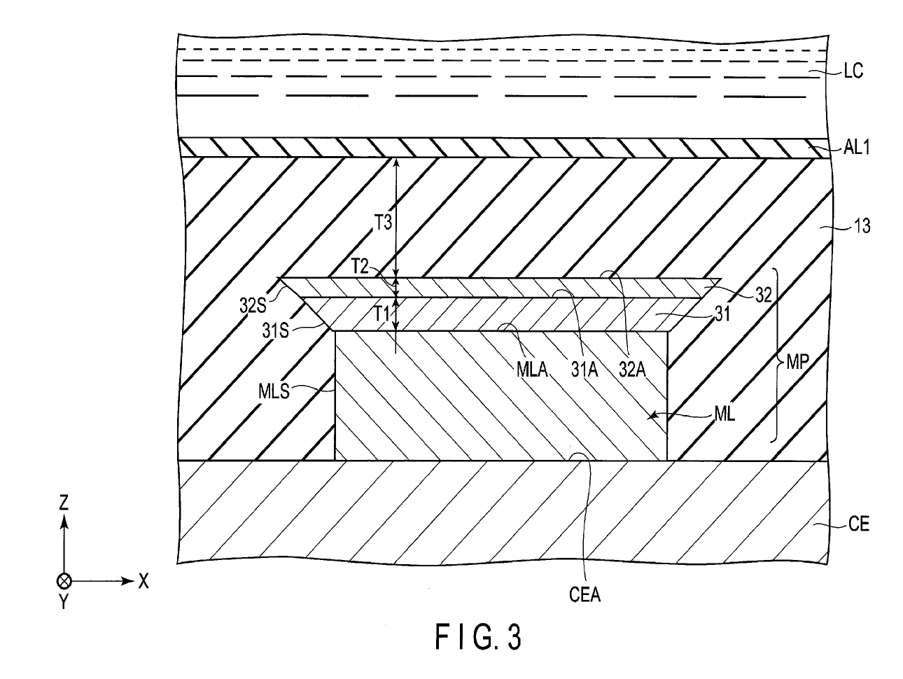

The metal wiring portion MP, which will be explained below with reference to FIG. 3, comprises a metal layer ML in a lowermost layer. The metal layer ML is in contact with the common electrode CE just above the signal line S and reduces the electric resistance of the common electrode CE. In the example illustrated in FIG. 2, the metal wiring layer MP is located on the common electrode CE but an insulating layer may be interposed between the common electrode CE and the metal wiring portion MP. In this case, the common electrode CE is electrically continuous with the metal wiring portion MP through a contact hole penetrating an insulating film.

The third insulating film 13 is located on the common electrode CE and the metal wiring portion MP. The third insulating film 13 is an inorganic insulating film and is formed of, for example, silicon nitride (SiN). The third insulating film 13 is an example of the insulating layer. The pixel electrode PE is located on the third insulating film 13. The pixel electrode PE is opposed to the common electrode CE via the third insulating film 13.

In addition, the pixel electrode PE has a slit SL at a position opposed to the common electrode CE. The pixel electrode PE is a transparent electrode formed of a transparent conductive material, similarly to the common electrode CE. For example, the common electrode CE corresponds to the first transparent electrode while the pixel electrode PE corresponds to the second transparent electrode. The first alignment film AL1 covers the pixel electrode PE and the third insulating film 13.

The constitution of the first substrate SUB1 is not limited to the example shown in FIG. 2, but the pixel electrode PE may be located between the second insulating film 12 and the third insulating film 13 and the common electrode CE may be located between the third insulating film 13 and the first alignment film AL1. In this case, the pixel electrode PE is shaped in a flat plate which does not have a slit while the common electrode CE has a slit opposed to the pixel electrode PE. In addition, the pixel electrode PE and the common electrode CE may be shaped in a comb tooth and may be disposed to be engaged with each other.

The second substrate SUB2 includes a second insulating substrate 20, a black matrix BM, a color filter CF, an overcoat layer OC, a second alignment film AL2, and the like. The second insulating substrate 20 has a main surface 20A opposed to the first substrate SUB1 and a main surface 20B opposed to the main surface 20A.

The black matrix BM and the color filter CF are disposed on the main surface 20A. The black matrix BM partitions the pixels PX. The black matrix BM is located just above the signal line S, i.e., the metal wiring portion MP to block external light traveling to the metal wiring portion MP and the signal line S and light reflected on the metal wiring portion MP and the signal line S.

The color filter CF is opposed to the pixel electrode PE and partially superposed on the black matrix BM. The color filter CF includes a red color filter, a green color filter, a blue color filter, and the like. The overcoat layer OC covers the color filter CF. The second alignment film AL2 covers the overcoat layer OC.

The color filter CF may be located on the first substrate SUB1. The color filter CF may include color filters of four or more colors. A first polarizer PL1 is interposed between the first insulating substrate 10 and the backlight unit BL. A second polarizer PL2 is disposed on the main surface 20B of the second insulating substrate 20. Retardation films and the like may be provided on the first polarizer PL1 and the second polarizer PL2 as needed. Light interference conditions of a first reflection suppressing layer 31 to be explained below may be adjusted by selecting optical characteristics of the second polarizer PL2.

FIG. 3 is an enlarged cross-sectional view showing an example of the metal layer ML. The metal wiring portion MP of the present embodiment comprises the metal layer ML, the first reflection suppressing layer 31 formed on the metal layer ML, and a second reflection suppressing layer 32 formed on the first reflection suppressing layer 31 as shown in FIG. 3.

The metal layer ML is in contact with an upper surface CEA of the common electrode CE. The metal layer ML is formed of metal materials such as molybdenum, tungsten, titanium and aluminum having a smaller electric resistance than the transparent conductive material or an alloy formed by combining these metal materials. The metal layer ML may have a single-layer structure or a multi-layer structure. The metal layer ML is an example of a metal line. The scanning line G and the signal line S as explained above are formed of the same metal material as the metal layer ML. Alternately, the scanning line G and the signal line S may be constituted similarly to the metal wiring portion MP.

The first reflection suppressing layer 31 is in contact with an upper surface MLA of the metal layer ML and covers the entire upper surface MLA. The first reflection suppressing layer 31 is formed of ITO or reduced ITO. The first reflection suppressing layer 31 is an example of the reduced ITO layer formed on the metal line. To obtain the first reflection suppressing layer 31 of reduced ITO, an ITO film may be formed and ITO may be reduced by plasma treatment. Examples of conditions for the plasma treatment are 200° C., 2.5 Torr, H2=300 sccm, 100 W, and 50 sec. Damage to ITO can be suppressed and ITO can be reduced under these conditions.

Reduced ITO has a smaller transparency than unreduced ITO and may be blackened. The common electrode CE is formed of unreduced ITO and has a higher transparency than the first reflection suppressing layer 31 formed of reduced ITO. In other words, the first reflection suppressing layer 31 has a high performance to absorb light of a visible light wavelength (in a range, for example, from 380 to 700 nm) as compared with the common electrode CE.

The second reflection suppressing layer 32 is in contact with an upper surface 31A of the first reflection suppressing layer 31 and covers the entire upper surface 31A. The second reflection suppressing layer 32 is brown or black. The second reflection suppressing layer 32 is formed of a material having a refractive index of 1 or more and a light absorption coefficient of 0.5 or more in a visible light range. An example of the material of the second reflection suppressing layer 32 is titanium nitride (TiN). The second reflection suppressing layer 32 is interposed between the first reflection suppressing layer 31 and the third insulating film 13 in a range superposed on at least the metal layer ML in planar view.

The third insulating film 13 is in contact with the upper surface CEA of the common electrode CE, the upper surface 32A of the second reflection suppressing layer 32, the side surface MLS of the metal layer ML, the side surface 31S of the first reflection suppressing layer 31, and the side surface 32S of the second reflection suppressing layer 32. The third insulating film 13 is formed of silicon nitride (SiN) and has a higher transparency than each layer of the metal wiring portion MP as explained above.

The first reflection suppressing layer 31 and the second reflection suppressing layer 32 are shaped in, for example, an overhang wider than the metal layer ML. Such a cross-section can be formed by, for example, depositing materials different in an etching speed. The metal layer ML is formed of the above-explained metal material while the first reflection suppressing layer 31 and the second reflection suppressing layer 32 are formed of the above-explained metal oxide or metal nitride.

The thickness of the first reflection suppressing layer 31, the thickness of the second reflection suppressing layer 32, and the thickness of the third insulating film 13 located just above the metal layer ML are denoted by T1, T2, and T3. In the metal layer ML of the display device DSP according to the present embodiment, the thickness T2 of the second reflection suppressing layer 32 is smaller than the thickness T1 of the first reflection suppressing layer 31, and the thickness T3 of the third insulating film 13 is larger than the thickness T1 and the thickness T2. For example, the thickness T1 of the first reflection suppressing layer 31 is desirably in a range from 30 to 50 nm. The thickness T2 of the second reflection suppressing layer 32 is desirably in a range from 20 to 30 nm. The thickness T3 of the third insulating film 13 is desirably in a range from 110 to 190 nm.

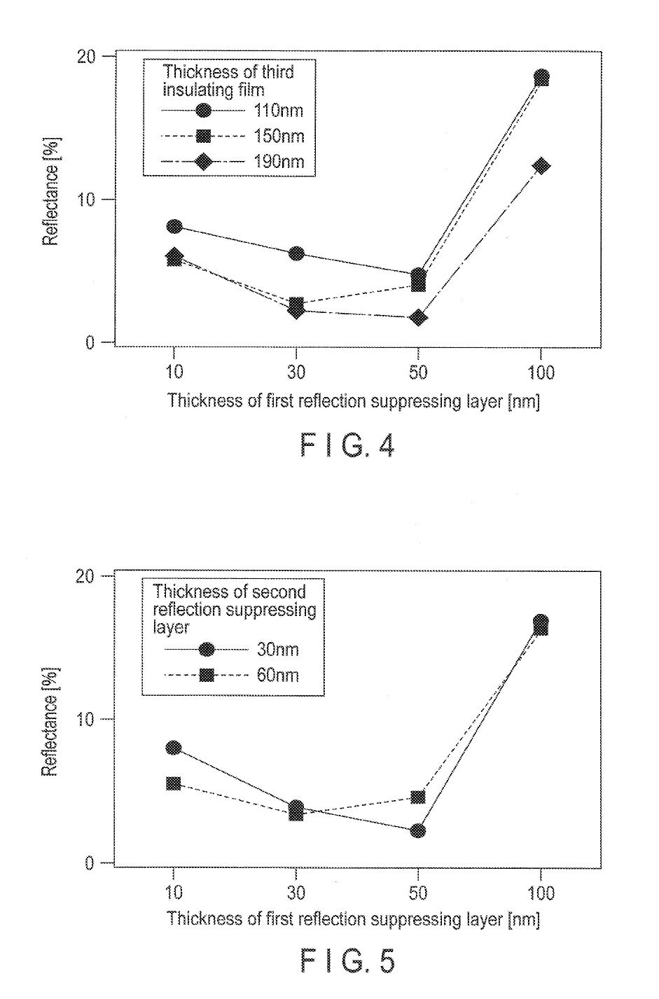

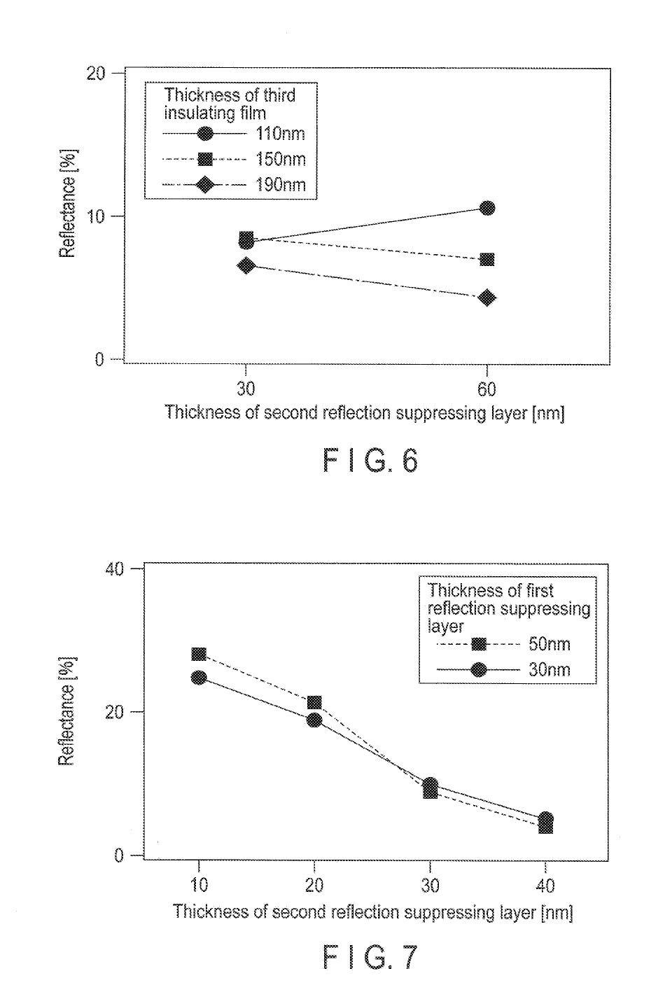

A relationship between the thickness T1, the thickness T2, and the thickness T3, and the light reflectance of the metal layer ML will be explained below with reference to FIG. 4 to FIG. 13. FIG. 4 is a graph showing an interaction between the thickness T1 of the first reflection suppressing layer 31 and the thickness T3 of the third insulating film 13 shown in FIG. 3. FIG. 5 is a graph showing an interaction between the thickness T1 of the first reflection suppressing layer 31 and the thickness T2 of the second reflection suppressing layer 32 shown in FIG. 3. FIG. 6 is a graph showing an interaction between the thickness T3 of the third insulating film 13 and the thickness T2 of the second reflection suppressing layer 32 shown in FIG. 3.

It is confirmed from the result of FIG. 4 that the minimum value of the reflectance is in the range from 30 to 50 nm of the thickness of the first reflection suppressing layer 31, in the relationship between the third insulating film 13 and the first reflection suppressing layer 31. It is also confirmed that the reflectance is lower as the thickness of the third insulating film 13 is larger.

It is also confirmed from the result of FIG. 5 that the minimum value of the reflectance is in the range from 30 to 50 nm of the thickness of the first reflection suppressing layer 31, in the relationship between the first reflection suppressing layer 31 and the second reflection suppressing layer 32.

It is confirmed from the result of FIG. 6 that the reflectance is lower as the thickness of the third insulating film 13 is larger, in the relationship between the third insulating film 13 and the second reflection suppressing layer 32. It is also confirmed that if the thickness of the third insulating film 13 is 190 nm, the reflectance is lower as the thickness of the second reflection suppressing layer 32 is larger.

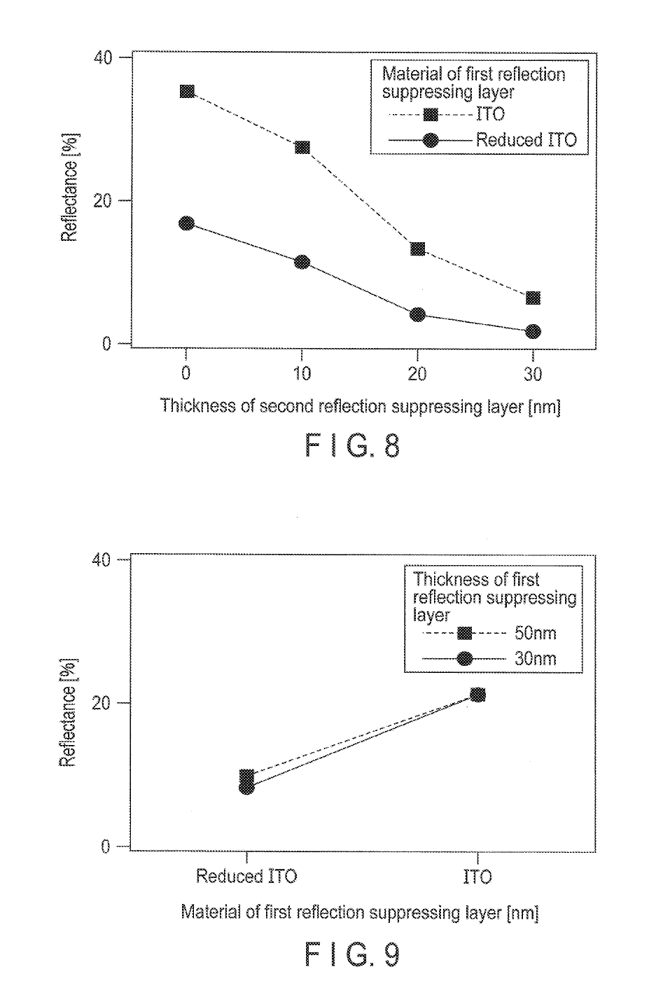

FIG. 7 is a graph showing an interaction between the thickness T2 of the second reflection suppressing layer 32 and the thickness T1 of the first reflection suppressing layer 31 shown in FIG. 3. FIG. 8 is a graph showing an interaction between the thickness T2 of the second reflection suppressing layer 32 and a material of the first reflection suppressing layer 31 shown in FIG. 3. FIG. 9 is a graph showing an interaction between the material of the first reflection suppressing layer 31 and the thickness T1 of the first reflection suppressing layer 31. If the first reflection suppressing layer 31 is reduced ITO, the light reflectance can be suppressed to one third or a half as compared with a case where the first reflection suppressing layer 31 is unreduced, as shown in FIG. 9.

It is confirmed from the result of FIG. 7 that the reflectance is lower as the thickness of the second reflection suppressing layer is larger, in the relationship between the first reflection suppressing layer 31 and the second reflection suppressing layer 32.

It is confirmed from the result of FIG. 8 that the reflectance is lower as the thickness of the second reflection suppressing layer is larger, in a case where the material of the first reflection suppressing layer 31 is either unreduced ITO or reduced ITO.

It is confirmed from the result of FIG. 9 that if the thickness of the first reflection suppressing layer 31 is 50 nm and 30 nm, the reflectance is lower in the case where the material of the first reflection suppressing layer 31 is reduced ITO than that in the case where the material of the first reflection suppressing layer 31 is unreduced ITO.

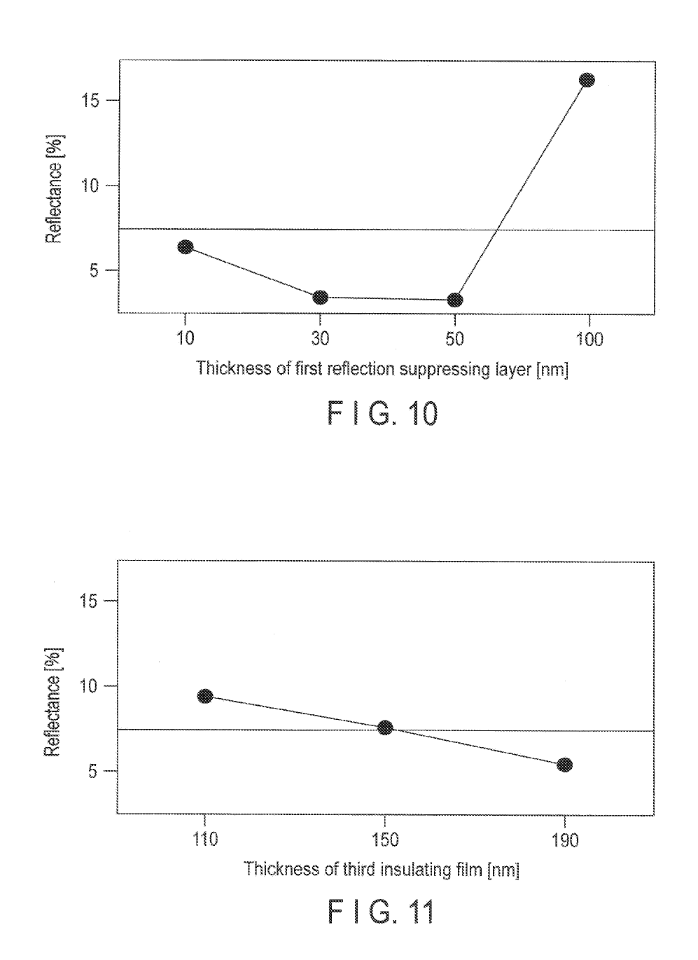

FIG. 10 is a graph showing a main effect of the thickness T1 of the first reflection suppressing layer 31 extracted by averaging the data of FIG. 4 and FIG. 5. As shown in FIG. 10, the light reflectance is minimized when the thickness T1 of the first reflection suppressing layer 31 is in a range from 30 to 50 nm. If the thickness T1 is smaller than this range, the light interference is smaller and the reflection cannot be sufficiently suppressed. If the thickness T1 is larger than this range, the designed light interference conditions are deviated and the reflectance is increased.

FIG. 11 is a graph showing a main effect of the thickness T3 of the third insulating film 13 extracted by averaging the data of FIG. 4 and FIG. 6. As shown in FIG. 11, the light reflectance is smoothly reduced as the thickness T3 of the third insulating film 13 is larger. However, making the thickness T3 of the third insulating film 13 larger than this is undesirable from the viewpoint of mass production of the display device DSP since the processing time is longer and the dust may occur inside the manufacturing device.

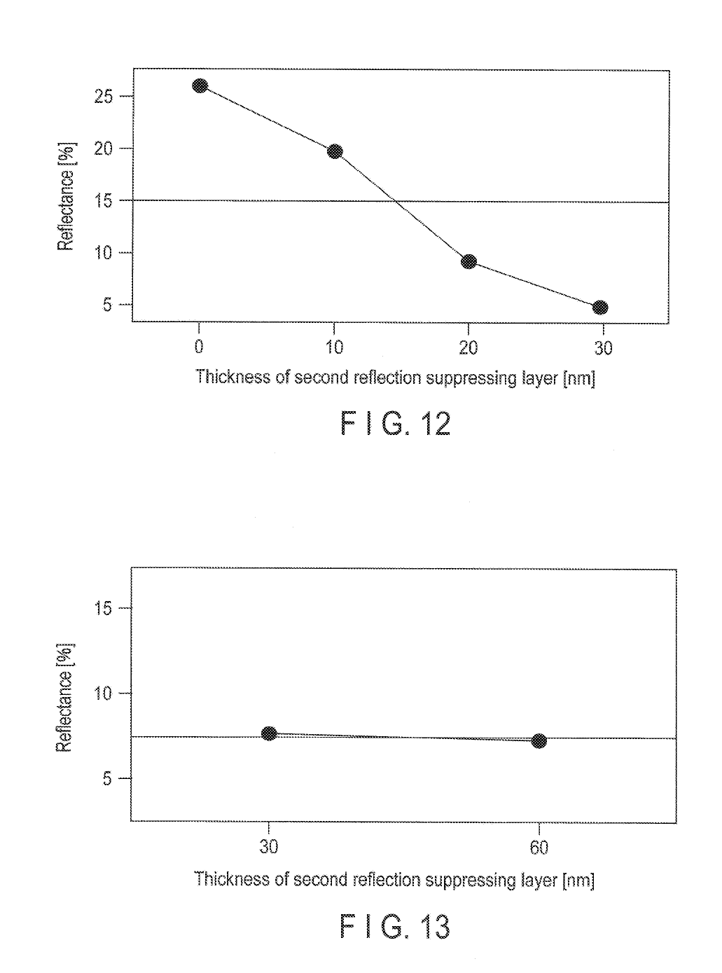

FIG. 12 is a graph showing a main effect of the thickness T2 of the second reflection suppressing layer 32 extracted by averaging the data of FIG. 7 and FIG. 8. FIG. 13 is a graph showing a main effect of the thickness T2 of the second reflection suppressing layer 32 extracted by averaging the data of FIG. 5 and FIG. 6. As shown in FIG. 12, when the thickness T2 of the second reflection suppressing layer 32 ranges from 0 to 30 nm the light reflectance is remarkably reduced as the thickness T2 of the second reflection suppressing layer 32 is larger. In contrast, as shown in FIG. 13, when the thickness T2 of the second reflection suppressing layer 32 exceeds 30 nm the light reflectance is reduced slightly even if the thickness T2 is increased.

The display device DSP configured as explained above comprises the metal layer ML formed of a metal having a smaller electric resistance than the transparent conductive material in the display area DA. For this reason, power consumption in the display area DA can be suppressed. Alternately, sensitivity of a touch panel and the like disposed in the display area DA can be improved. The material of the metal layer ML is, for example, molybdenum tungsten.

The upper surface MLA of the metal layer ML covers the first reflection suppressing layer 31 which suppresses light reflection. For this reason, even if the metal layer ML is disposed in the display area DA, external light is reflected on the metal layer ML and degradation in display quality of the display device DSP can be suppressed.

ITO or reduced ITO of which the first reflection suppressing layer 31 is formed suppresses reflection by light interference. If the same advantages as ITO or reduced ITO are to be obtained from the material which suppresses the reflection by light absorption, thickness of the reflection suppressing layer needs to be remarkably larger. If the reflection suppressing layer is formed of TiN, thickness needs to be 200 nm or more to obtain the same advantages as ITO having the thickness of 50 nm.

In the present embodiment, the first reflection suppressing layer 31 is formed of ITO or reduced ITO. For this reason, a sum of the thickness T1 of the first reflection suppressing layer 31 and the thickness T2 of the second reflection suppressing layer 32 can be reduced remarkably as compared with a case where the reflection suppressing layers are formed of a material suppressing the reflection by light absorption.

In general, the third insulating film 13 covering the common electrode CE is formed of SiN. If ITO or reduced ITO is directly covered with SiN, the light interference conditions are changed in the interface between ITO (reduced ITO) and SiN and the external light is reflected on the upper surface 31A of the first reflection suppressing layer 31.

In the present embodiment, the upper surface 31A of the first reflection suppressing layer 31 is covered with the second reflection suppressing layer 32. The light reflection is suppressed to a minimum level at an interface between the first reflection suppressing layer 31 and the second reflection suppressing layer 32. For this reason, the light interference conditions of the first reflection suppressing layer 31 are not deviated even if the third insulating film 13 and the like are deposited on the second reflection suppressing layer 32.

The material of the second reflection suppressing layer 32 is desirably TiN. TiN can suppress the light reflection at the interface between the first reflection suppressing layer 31 and the second reflection suppressing layer 32 to the minimum level. Furthermore, external light of the traveling passage which is made incident on the first reflection suppressing layer 31 and external light of the return passage which is transmitted through the first reflection suppressing layer 31 and reflected on the metal layer ML can be absorbed and attenuated twice by the property of TiN of absorbing light. Moreover, since TiN is the material generally used in the steps of manufacturing the display device DSP, burden on mass production of the display device DSP is small.

In the present embodiment, the thickness T1 of the first reflection suppressing layer 31 is in a range from 30 to 50 nm. If the thickness T1 is in this range, the light reflectance can be minimized. In addition, the thickness T2 of the second reflection suppressing layer 32 is in a range from 20 to 30 nm. If the thickness T2 is smaller than 20 nm, the light reflectance is increased remarkably. Even if the thickness T2 exceeds 30 nm, the light reflectance is reduced only slightly. In contrast, if the thickness T2 exceeds 30 nm, warp of the first substrate SUB1 and occurrence of dust caused by the residual stress of the second reflection suppressing layer 32 become remarkable. If the thickness T2 is in a range from 20 to 30 nm, sufficient suppression of light reflection and yields of the display device DSP can be achieved together.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device, comprising:
a metal line;
a first reflection suppressing layer formed on the metal line; and
a second reflection suppressing layer formed on the first reflection suppressing layer,
the first reflection suppressing layer being formed of indium tin oxide or reduced indium tin oxide.

2. The display device of claim 1, wherein
the second reflection suppressing layer absorbs a visible light wavelength.

3. The display device of claim 1, wherein
the second reflection suppressing layer is formed of titanium nitride.

4. The display device of claim 1, wherein
a thickness of the second reflection suppressing layer is smaller than a thickness of the first reflection suppressing layer.

5. The display device of claim 1, further comprising:
an insulating layer formed on the second reflection suppressing layer,
wherein
a thickness of the insulating layer is larger than the thickness of any one of the first reflection suppressing layer and the second reflection suppressing layer.

6. The display device of claim 1, further comprising:
a first transparent electrode,
wherein
the metal line is electrically connected to the first transparent electrode.

7. The display device of claim 1, further comprising:
a first transparent electrode;
a second transparent electrode; and
an insulating layer located between the first transparent electrode and the second transparent electrode,
wherein
the metal line is formed on the first transparent electrode, and
the insulating layer is formed on the second reflection suppressing layer.

8. The display device of claim 1, further comprising:
a first insulating substrate;
a first transparent electrode formed on the first insulating substrate; and
an insulating layer formed on the first transparent electrode,
wherein
the metal line is formed on the first transparent electrode, and
the insulating layer covers the first transparent electrode, the metal line, the first reflection suppressing layer, and the second reflection suppressing layer.

9. A display device, comprising:
a metal line;
a reduced ITO layer formed on the metal line; and
a titanium nitride layer formed on the reduced ITO layer,
the metal line, the reduced ITO layer, and the titanium nitride layer being covered with an insulating film formed of silicon nitride.

10. The display device of claim 9, wherein
a thickness of the titanium nitride layer is smaller than a thickness of the reduced ITO layer.

11. The display device of claim 9, wherein
a thickness of the insulating film is larger than the thickness of any one of the reduced ITO layer and the titanium nitride layer.

12. The display device of claim 9, wherein
the insulating film covers the metal line, the reduced ITO layer and the titanium nitride layer.
